(19) United States
(12) Patent Application Publication
(10) Pub. No.: US 2026/0234785 A1
(43) Pub. Date: Aug. 13, 2026

(54) NANOFABRICATED PATTERNED MESOSCOPIC CIRCUITS ON DIAMOND ANVILS

(71) Applicant: Washington University, St. Louis, MO (US)

(72) Inventors: Zackary Rehfuss, St. Louis, MO (US); Kaiwen Zheng, St. Louis, MO (US); Sheng Ran, St. Louis, MO (US); Kater Murch, St. Louis, MO (US)

(73) Assignee: Washington University, St. Louis, MO (US)

(21) Appl. No.: 19/537,482

(22) Filed: Feb. 11, 2026

Related U.S. Application Data
(60) Provisional application No. 63/757,129, filed on Feb. 11, 2025.

(51) Int. Cl. C23C 14/06; C23C 14/35; C23C 16/27; C30B 25/10; C30B 25/20

(52) U.S. Cl. CPC C23C 14/0641; C23C 14/35; C23C 16/274; C30B 25/105; C30B 25/20

(57) ABSTRACT

A process for fabricating a mesoscopic circuit on a diamond surface for use in diamond anvil cell experiments is disclosed that includes mounting a diamond on a flat substrate to ensure a flat surface for fabricating the mesoscopic circuit; spin-coating the diamond surface with a bi-electron beam resist layer to form a bottom resist layer in direct contact with the diamond surface and a top resist layer over the bottom resist layer; depositing a metal layer over the bi-electron beam resist layer; removing a portion of the metal layer and bi-electron beam resist layer to expose a portion of the diamond surface in a pattern corresponding to one or more elements of the mesoscopic circuit; depositing electrically conductive layer(s) over the diamond surface and surrounding metal layer; and lifting off the unwanted portion of the at least one conductive layer, metal layer and resist layer to expose the mesoscopic circuit.

### CROSS-REFERENCE TO RELATED APPLICATIONS

This application claims the benefit of priority to U.S. Provisional Application Ser. No. 63/757,129 filed on Feb. 11, 2025, which is incorporated herein by reference in its entirety.

### STATEMENT REGARDING FEDERALLY SPONSORED RESEARCH OR DEVELOPMENT

This invention was made with government support under DMR2236528 awarded by the National Science Foundation. The government has certain rights in the invention.

### MATERIAL INCORPORATED-BY-REFERENCE

Not applicable.

### FIELD OF THE INVENTION

The present disclosure generally relates to methods of fabricating complex mesoscopic circuits on diamond culets and methods of use thereof.

### BACKGROUND OF THE INVENTION

External pressure is a fundamental thermodynamic variable intricately linked to thermodynamic equation of state for a given material. By controlling the external pressure on a material sample, one can selectively tune the properties of the material. Historically, controlling the application of high pressure to a sample has lagged behind other thermodynamic variables such as temperature or magnetic field. To overcome the challenge of tuning pressures into the high-pressure regime (P>3 GPa) which is the limit for most hydrostatic piston cylinder cells, much work has been done in the last century to invent new pressure cell mechanisms that can push pressure into the Terapascal range.

The diamond anvil cell (DAC) has been utilized to perform infrared spectroscopy experiments on calcite and aragonite. The DAC involved clamping powders of interest directly between two diamonds with no gasket or pressure medium. In subsequent experiments, a metal gasket with a hole was introduced. Additional refinements included close alignment of the diamonds, as well as additional enhancements to achieve sample pressures up to 40 GPa. A ruby pressure scale was developed that measured pressure changes by measuring the shift of the ruby R1 and R2 lines. Diamonds with beveled anvils were incorporated into the DAC to achieve static pressures well above 100 GPa. To date, the highest static pressures generated are Tera-pascal pressures.

Early experimental techniques done inside a DAC were performed using optical measurements. Later DAC experiments included a two-wire measurement scheme with a gasketed cell and a liquid pressure medium. Subsequent DAC experiments have introduced electrically conductive leads into the diamond anvil cell sample space to perform electrical measurements at high pressures. The advent of sputtered electrical contacts for precision electrodes paved the way for the modern-day techniques developed for patterned diamond anvils.

However, sputter-deposited leads were vulnerable to shearing under the stress generated by the extremely high pressures associated with DAC experiments. Recently, a process of encapsulating the electrode circuits under epitaxially grown diamonds developed that yielded designer diamonds capable of withstanding very high pressures but suffered from a key limitation of reproducibility for other researchers. Further, this encapsulation process required complex custom-built equipment for the depositions and violent mechanical polishing after the encapsulation which is not suited for experiments on thin film samples that are fabricated on the culet of the diamond.

Other materials have been used for encapsulation of samples on the diamond surface of a DAC such as Al₂O₃ that is much easier to deposit than diamond encapsulation layers, rendering the DAC experimental method of ultrahigh-pressure research to any group that has access to standard clean-room equipment.

### SUMMARY OF THE INVENTION

Among the various aspects of the present disclosure is the provision of a process to fabricate mesoscopic circuits on diamond anvils.

In accordance with another aspect of the present disclosure, a process for fabricating a mesoscopic circuit on a diamond surface for use in diamond anvil cell (DAC) experiments is provided. The process comprises providing a diamond and a flat substrate; mounting the diamond pressed flat against the flat substrate to ensure a flat surface for fabricating the mesoscopic circuit; spin-coating the diamond surface with a bi-electron beam resist layer comprising a bottom resist layer in direct contact with the diamond surface and a top resist layer over the exposed surface of the bottom resist layer; depositing a metal layer over the bi-electron beam resist layer; removing a selected portion of the metal layer and underlying bi-electron beam resist layer to expose a portion of the diamond surface in a pattern corresponding to one or more elements of the mesoscopic circuit using an E-lithography system; depositing at least one electrically conductive layer over the exposed diamond surface and surrounding metal layer; and lifting off the unwanted portion of the at least one conductive layer and underlying metal layer and bi-electron beam resist layer to expose the mesoscopic circuit on the diamond surface.

In one aspect, the diamond is a type IIa single-beveled diamond with a 400 μm wide culet. In another aspect, the flat substrate comprises silicon (Si). In another aspect, the flat substrate comprises a 1 cm² carrier chip hand cleaved from a Si (100) wafer. In another aspect, the top resist layer comprises a ZEP 520A-7 copolymer and the bottom resist layer comprises a EL 13 copolymer. In another aspect, the top resist layer comprises a thickness of 270 nm and the bottom resist lay comprises a thickness of 1460 nm. In another aspect, the top resist layer and the bottom resist layer are spin coated onto the diamond surface at a spin rate of about 3000 RPM of spin rate and soft baked at about 180° C. for about 2 minutes. In another aspect, the metal layer comprises (aluminum) Al. In another aspect, the Al is deposited over the bi-electron beam resist layer using a magnetron sputter chamber or an electron bean evaporation chamber with a base pressure ranging from 10⁻⁶ to 10⁻⁷ Torr. In another aspect, the process further comprising cleaning the diamond in at least one ultrasound bath, each ultrasound bath containing one of toluene to remove silver epoxy, acetone to remove any oils, aqua regia to dissolve attached metals, Cr etchant to dissolve attached Cr, Nb etchant to dissolve attached Nb, or piranha solution to dissolve attached organic residue. In another aspect, the diamond is cleaned in each ultrasound bath for a duration of about 10 minutes. In another aspect, mounting the diamond to the flat substrate comprises attaching the diamond to the Si flat substrate using a silver epoxy adhesive. In another aspect, each of the at least one conductive layer comprises a metal independently selected from Al, Au, Cr, Ta, Ti, Nb, W, Al₂O₃, SiO₂, any alloy thereof, and any combination thereof. In another aspect, the process further comprising preparing the exposed diamond surface for deposition of the at least one conductive layer using an O₂ plasma ashing treatment. In another aspect, the process further comprising soaking the diamond mounted to the flat substrate in Kayaku Remover PG at a temperature of about 65° C. for a duration of about 12 hours. In another aspect, the process further comprising removing the diamond from the flat substrate. In another aspect, the mesoscopic circuit is selected from an 8-lead electrode pattern, a 10-lead electrode pattern, at least two parallel leads, a pair of intercalated fingers, and any combination thereof. In another aspect, mesoscopic circuit comprises a minimum feature size of about 500 nm. In another aspect, the process further comprising removing an amount of silver epoxy from the diamond by abrasion, sonication in toluene, and any combination thereof.

In accordance with a further aspect of the present disclosure, a patterned diamond comprising a mesoscopic circuit formed on a diamond surface using a fabrication process is provided. The fabrication process comprises providing a diamond and a flat substrate; mounting the diamond pressed flat against the flat substrate to ensure a flat surface for fabricating the mesoscopic circuit; spin-coating the diamond surface with a bi-electron beam resist layer comprising a bottom resist layer in direct contact with the diamond surface and a top resist layer over the exposed surface of the bottom resist layer; depositing a metal layer over the bi-electron beam resist layer; removing a selected portion of the metal layer and underlying bi-electron beam resist layer to expose a portion of the diamond surface in a pattern corresponding to one or more elements of the mesoscopic circuit using an E-lithography system; depositing at least one electrically conductive layer over the exposed diamond surface and surrounding metal layer; and lifting off the unwanted portion of the at least one conductive layer and underlying metal layer and bi-electron beam resist layer to expose the mesoscopic circuit on the diamond surface.

Other objects and features will be in part apparent and in part pointed out hereinafter.

### DESCRIPTION OF THE DRAWINGS

Those of skill in the art will understand that the drawings, described below, are for illustrative purposes only. The drawings are not intended to limit the scope of the present teachings in any way.

FIG. 1 is a block diagram schematically illustrating steps of a process to fabricate electrical leads on a diamond anvil. In step (a) a diamond is cleaned following the procedure described herein; inset shows a picture of the as cleaned culet of a diamond. In step (b), the cleaned diamond is fixed to a Si carrier wafer and attached using silver epoxy. In step (c), the bilayer electron beam resist is spin coated onto the diamond, then an aluminum discharge layer is deposited on the surface using RF magnetron sputtering. In step (d), the leads are formed using electron beam lithography. In step (e), trilayer Ti/Cr/Au metal contacts are deposited using electron beam evaporation. In step (f), a standard lift-off procedure is performed by soaking within Kayaku Remover PG leaving behind the patterned electrical leads on the diamond surface suitable for use as a diamond anvil.

FIG. 2A is a backscattered scanning electron microscope image of patterned metal structures on diamond culet, showing 1 μm leads with 1 μm spacing in between.

FIG. 2B is a backscattered scanning electron microscope image of patterned metal structures on diamond culet, showing 500 nm leads with 500 nm spacing in between.

FIG. 3A is an image of a patterned diamond for electrical transport measurements, showing the diamond with contact leads on the culet and the facets.

FIG. 3B is an image of the patterned diamond of FIG. 3A with a bulk sample placed onto the contact leads.

FIG. 3C is an image of the patterned diamond of FIG. 3B after spin coating a layer of SU-8 photoresist on top of the bulk sample and contact leads.

FIG. 4 is a block diagram schematically illustrating a process to fabricate metallic structures on diamond culets and facets with feature sizes as small as 500 nm.

FIG. 5A is a backscattered scanning electron microscope image of Nb/Al intercalated electrode test structures with 1 μm critical feature size formed on diamond culets and facets using the fabrication method as disclosed herein.

FIG. 5B is a backscattered scanning electron microscope image of Ti/Cr/Au leads with 500 nm critical feature size formed on diamond culets and facets using the fabrication method as disclosed herein.

FIG. 6A is a photo of a metallic liftoff structure on a diamond culet and facets.

FIG. 6B is a photo of a metallic liftoff structure on a diamond culet and facets.

FIG. 7A is a photo of a patterned diamond with a bulk sample placed onto the contact leads.

FIG. 7B is an image of a patterned diamond with a bulk sample of FIG. 7A after multiple experiments.

FIG. 8 is a graph summarizing the resistance measured across leads formed on a patterned diamond. The leads remained functional at temperatures representative of liquid nitrogen and exhibited metallic resistance-temperature behavior.

FIG. 9A is a photo of a 10-lead W device used for the Zr experiment. The metallic islands on the opposing corner of the culet are used to focus the electron beam and to find the center of the culet.

FIG. 9B is a photo of a 12-lead W device for electrical resistivity measurement. The leads trace continuously from the culet to the facets.

FIG. 9C is a photo of Nb/Al finger capacitors.

FIG. 9D is a photo of a concentric microwave antenna patterned onto 50 μm culet.

FIG. 10A is an exploded side view schematic of a loaded diamond anvil cell (DAC) used to measure a Zr sample.

FIG. 10B is a white light image taken through the 10-lead W device patterned diamond with a Zr sample at 51.1 GPa. The 4 wire measurement configuration used for all resistance measurements is shown in black. The 10 leads are clearly seen with no signs of wear up at pressure up to 51.1 GPa.

FIG. 10C is a graph of ruby florescence collected from a small pile of ruby powder placed in the pressure media directly over the top of the sample. The solid and dashed lines are the spectra before cooling (BC) and after warming up (AW) the clamped cell. The fluorescence profile was used to calculate the pressure. The average of the pre-and post-cool down pressures was used as the reported pressure.

FIG. 10D is a graph of temperature dependence of the electrical resistance measured with the 10-lead W device below and above the HCP to BCC structural transition, showing the dramatic enhancement of the critical temperature. The higher pressure (green) data shows signs of pressure inhomogeneity with a clear double transition. This is also reflected in the florescence spectrum with the prominent double shoulder. The inhomogeneity is expected at these high pressures with a solid pressure medium on such a large sample.

FIG. 11 is a schematic diagram of a representative arrangement of components within a diamond anvil cell (DAC).

### DETAILED DESCRIPTION OF THE INVENTION

The present disclosure is based, at least in part, on the development of a process to fabricate mesoscopic circuits on diamond anvils.

In various aspects, a high-yield fabrication process of complex mesoscopic circuits on a diamond culet surface for use as a diamond anvil in an ultra-high pressure diamond anvil cell (DAC) is described herein that overcomes one or more of at least several limitations of existing fabrication processes. The disclosed fabrication process is compatible with implementation in typical academic clean-room environments and yields circuits with feature sizes as small as about 500 nm. Further, the circuits fabricated using the disclosed methods are strongly adhered to the diamond surface and resistant to shearing at the ultrahigh pressures associated with DAC experiments, extending the working life of the diamond anvils formed in this manner.

In various aspects, the disclosed fabrication process incorporates at least several elements developed and optimized to enhance various aspects of the resulting diamond anvil. In some aspects, a procedure for electron beam lithography was developed to obtain good focus at the diamond culet, enabling the ability to produce mesoscopic circuits with feature sizes as small as about 500 nm with lift-off metal layers. In other aspects, treating the diamond surface before metal deposition and including a Ti buffer layer in the circuit elements provides strong adhesion of the mesoscopic circuit elements to the diamond surface.

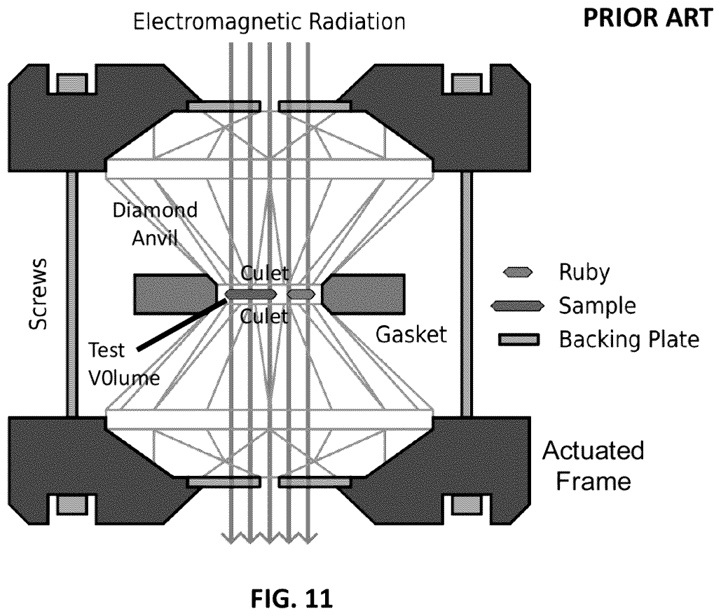

In various aspects, the disclosed fabrication process is used to produce patterned diamonds comprising a mesoscopic circuit on the surface of a diamond used as a diamond anvil within a high-pressure diamond anvil cell (DAC). By way of non-limiting example, a schematic diagram of a representative DAC is shown illustrated as FIG. 11. In the DAC, a pair of diamond anvils are mounted in an actuated framework with their respective culet surfaces aligned. A sample and optionally ruby dust are positioned between the culet surfaces and sealed within a test volume defined by the two culet surfaces and the inner surface of a surrounding gasket. The gasket is formed from a material characterized by high stiffness and high melting point to withstand the high temperatures and pressures within the volume during compression of the sample including, but not limited to, rhenium (Re).

Referring again to FIG. 11, the actuated frame includes an actuation means configured to move the culet surfaces toward one another, causing the test volume and the test volume's pressure to increase. The DAC may be optionally provided with various additional elements including cooling systems and devices to actively cool the test volume, light-based measurement systems and devices, electrical elements, systems, and devices, and any combination thereof. Non-limiting examples of light-based measurement systems and devices include systems and devices configured to implement optical imaging, fluorescent measurements, interferometry, and any other suitable light-based measurement method without limitation. Non-limiting examples of electrical systems and devices include systems and devices configured to implement various electromagnetic measurements, including voltage, current, resistance, capacitance, impedance, magnetic forces, and any other suitable electromagnetic measurement without limitation. By way of non-limiting example, a DAC system is described in Dubrovinskaia et al. (2016) “Terapascal static pressure generation with ultrahigh yield strength nanodiamond”, Science Advances 2, e1600341(2016), the content of which is incorporated by reference.

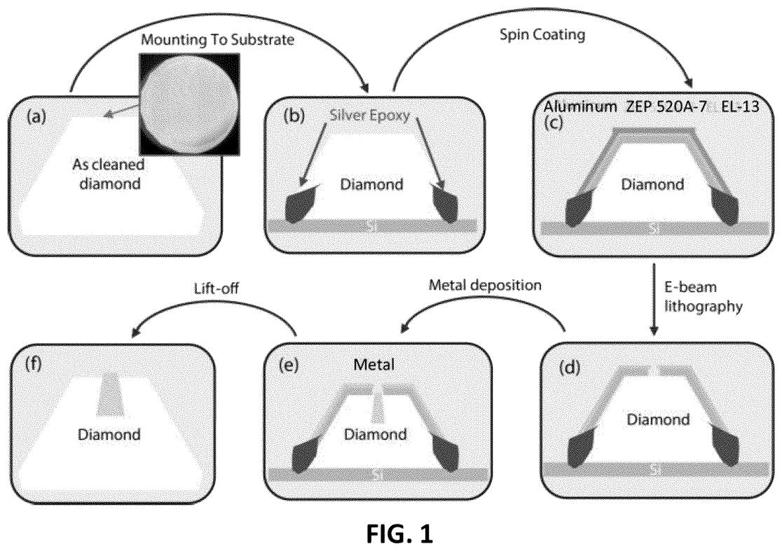

A schematic illustration of the disclosed fabrication process is shown illustrated as FIG. 1. As illustrated in FIG. 1, the process includes providing a suitable diamond (not illustrated) and cleaning the diamond at step a) in preparation for subsequent steps of the process. Any diamond suitable for use as a diamond anvil in a DAC system may be used including, but not limited to, new diamonds and diamonds previously used in a DAC system that include various attached or adhered materials. In some aspects, the materials attached or adhered to the surface of used diamonds include, but are not limited to, silver epoxy, circuit elements, previous test samples, and any other remnant of previous use as a diamond anvil in a DAC system. Non-limiting examples of suitable diamonds include a type IIa single-beveled diamond with a 400 μm wide culet.

In various aspects, the diamond is cleaned to remove materials from previous usage described above as well as oils associated with handling and/or previous use. In various aspects, cleaning the diamond may include at least one cleaning phase selected from of use of an ultrasonic bath containing toluene to remove silver epoxy from previous experiments, use of an ultrasonic bath inside acetone to remove any oils, an ultrasonic bath inside aqua regia to dissolve attached metals, use of an ultrasonic bath inside Cr etchant to dissolve attached Cr, use of an ultrasonic bath inside transcene Nb etchant to dissolve attached Nb, use of an ultrasonic bath inside piranha solution to dissolve attached organic residue, use of an ultrasonic bath inside any other suitable solvent to remove any additional attached materials, and any combination thereof. In various aspects, the duration of the each ultrasonic bath may be independently selected from a duration ranging from about 1 minute to about 20 minutes or more. In an exemplary aspect, the duration is about 10 minutes.

Referring again to FIG. 1, the disclosed process further includes mounting the cleaned diamond onto a flat substrate, shown illustrated by the inset image accompanying step a. In various aspects, the flat substrate material is selected from any suitable material including, but not limited to, silicon (Si). Without being limited to any particular theory, the flat substrate material is selected to have a microscopically flat surface to ensure that the diamond table surface is in direct contact with the flat substrate surface, ensuring that the culet surface of the mounted diamond is oriented in a relatively flat position for subsequent process steps described herein. By way of non-limiting example, the flat substrate may be a 1 cm² carrier chip hand cleaved from a typical n-type Si (100) wafer.

Referring again to FIG. 1, at least two corners of the mounted diamond are secured into place on the flat substrate at step b) using any suitable adhesive including, but not limited to, a silver epoxy adhesive. Non-limiting examples of suitable adhesives include EPO-TEK H20E silver epoxy.

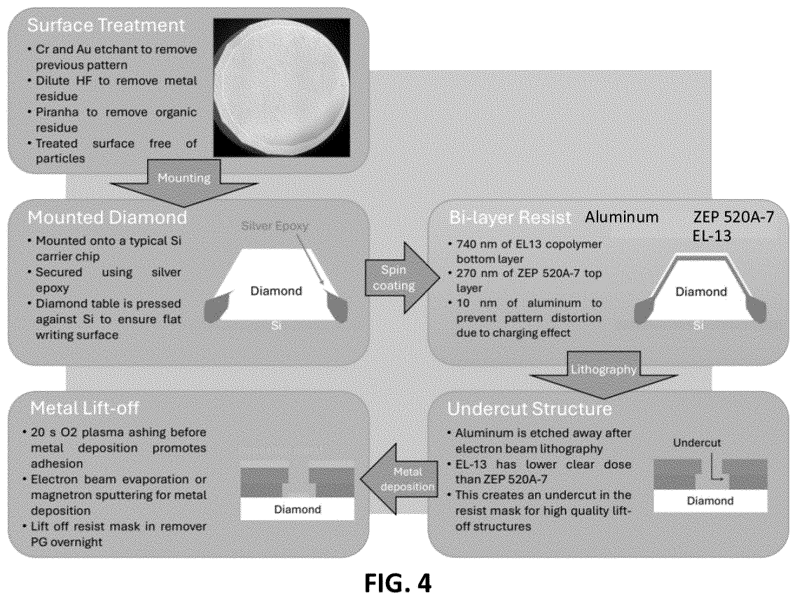

Referring again to FIG. 1, the culet and adjacent facets of the mounted diamond are spin-coated with several material layers at step c) to prepare for E-beam lithography of the metallic mesoscopic circuit elements in subsequent steps. In various aspects, the material layers include a bi-electron beam resist layer that includes a bottom resist layer in direct contact with the diamond surface and a top resist layer fabricated over the exposed surface of the bottom resist layer opposite the diamond surface. In various aspects, the top resist layer has a larger clear dose than the bottom resist layer, providing for the formation of an undercut. This allows the bottom layer to form an undercut structure (see FIG. 4) in which the openings etched into the top resist layer are narrower than the underlying opening through the bottom resist layer, Without being limited to any particular theory, the undercut structure is thought to improve the quality of the lift-off structures formed in subsequent steps of the disclosed process.

Any suitable electron beam resist materials may be used to form the bi-electron beam resist layer including, but not limited to, Kayaku PMMA copolymer EL 13 and ZEP 520A-7. By way of non-limiting example, the top and bottom layers may be spin coated onto the diamond surface at a spin rate of about 3000 RPM of spin rate and soft backed at about 180° C. for about 2 minutes. Non-limiting examples of a suitable bottom resist layer include Kayaku PMMA copolymer EL 13 at a thickness of about 730 nm. Non-limiting examples of a suitable top resist layer include ZEP 520A-7 at a thickness of about 270 nm.

Referring again to FIG. 1, the disclosed process further includes depositing a metal layer comprising Al over the bi-electron beam resist layer at step c). By way of non-limiting example, a 10 nm layer of Al is deposited on top of the bi-electron beam resist layer inside a Kurt J. Lesker PVD 75 DC magnetron sputter chamber with a base pressure of 10⁻⁶ Torr to prevent the pattern from distortion due to charging effects during electron beam lithography.

Referring again to FIG. 1, the coated diamond mounted on the flat substrate is loaded into an E-beam lithography system and the Al and bi-electron beam resist layers are removed in a pattern corresponding to the desired elements of the metallic mesoscopic circuit elements at step d). Any suitable lithography system may be used in the disclosed process without limitation. Non-limiting examples of suitable lithography systems include an Elionix ELS-S50EX lithography system.

By way of non-limiting example, the E-beam lithography system is operating by focusing the electron beam following the standard operational procedure of the tool, followed by identifying and positioning the electron beam on a reference point of the culet surface to establish a lithography coordinate system within which the lithography pattern may be accurately positioned. In some aspects, the vertices of the diamond, which are positioned at known dimensions around the culet surface, may be used to establish the lithography coordinate system.

By way of non-limiting example, the lithography coordinate system may be established using the diamond girdle vertices. The diamond girdle vertices are located at a known distance, for example, about 1 mm away from the culet; diamond girdle vertices may be located without exposing the culet to the electron beam. The coordinate of each vertex is recorded to construct a regular hexadecagon, within which the location of the center of the culet may be determined within about 20 μm accuracy. The E-beam is then jogged to one of the corners of the culet and focused on that corner by adjusting the Z-height of the sample stage of the lithography system. The beam is then focused to a size of 1 μm so that only a negligible fraction of the corner is exposed during this procedure. A GenISys BEAMER may be used to correct for proximity effects when the mesoscopic circuit features are too close to each other. After the lithography step, the resist is developed at room temperature in ZED-N 50 for 1 minute and in a 1:3 mixture of MIBK:IPA for 2 minutes.

Referring again to FIG. 1, the metal material forming the mesoscopic circuit is deposited over the patterned resist at step e). Before depositing metal, the diamond surface may be prepared with a O₂ plasma ashing treatment (20 s long, 100 W power, 15 sccm of O₂ flow) to promote adhesion. The diamond mounted on the flat substrate is then loaded into a Kurt J. Lesker PVD 75 electron beam evaporator with a base pressure of 10⁻⁸ Torr) and sequentially deposited with 65 nm of Ti at 0.8 nm/s, 20 nm of Cr at 0.8 nm/s, and 45 nm of Au at 0.8 nm/s.

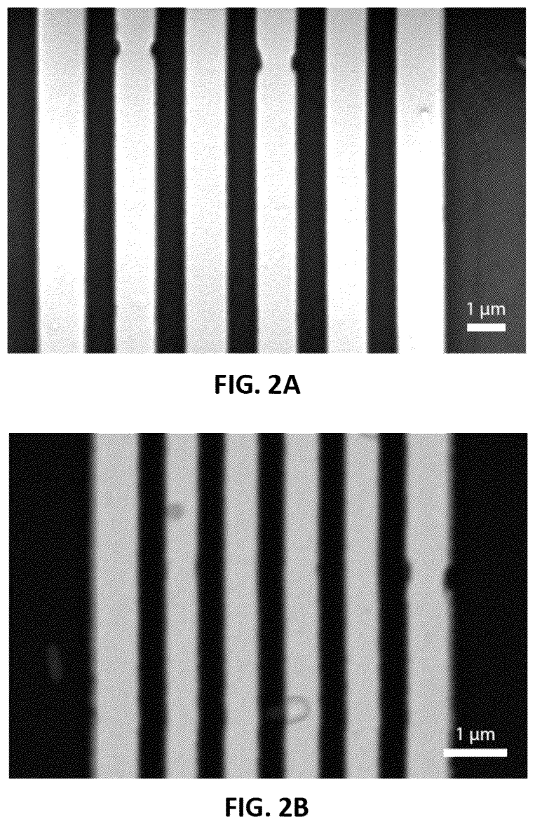

Referring again to FIG. 1, following deposition of the metal material over the patterned resist, the unwanted metal, underlying resist, and silver epoxy adhesive bonding the diamond to the flat substrate are removed. In some aspects, the diamond attached to the flat substrate is soaked in Kayaku Remover PG at 65° C. for 12 hours to lift-off the unwanted metal and other material. The silver epoxy used to attach the diamond onto the flat substrate softens inside the Remover PG and the patterned diamond can be easily detached from the carrier wafer. The diamond should be free of any silver residue after lift-off but can be further cleaned by careful abrasion cleaning followed by sonication in toluene if needed. Using the procedures described above, features down to 500 nm can be repeatably achieved as shown in FIGS. 2A and 2B.

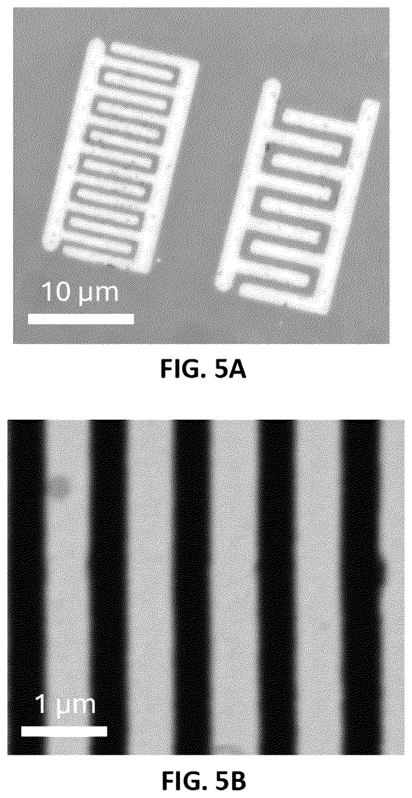

In various aspects, any suitable mesoscopic circuit may be fabricated onto the diamond surface of a diamond anvil using the disclosed procedure without limitation. In some aspects, the mesoscopic circuit has features with minimum dimensions as low as about 500 nm. Non-limiting examples of suitable mesoscopic circuit elements include leads, intercalated electrodes, and any other suitable circuit element without limitation. By way of non-limiting example, the mesoscopic circuit may include intercalated electrode test structures with 1 μm critical feature size as shown in FIG. 5A, leads with 500 nm critical feature size as shown in FIG. 5B, or 1 μm leads with 1 μm spacing in between as shown on FIG. 2A.

In various aspects, the features of the mesoscopic circuit elements may include any conductive metal compatible with the disclosed fabrication method without limitation. Non-limiting examples of suitable conductive metals include Al, Au, Cr, Ti, Nb, W and any alloy or combination thereof. In some aspect, the features of the mesoscopic circuit elements may include discrete layers of a different conductive metals or conductive metal alloys.

Definitions and methods described herein are provided to better define the present disclosure and to guide those of ordinary skill in the art in the practice of the present disclosure. Unless otherwise noted, terms are to be understood according to conventional usage by those of ordinary skill in the relevant art.

In some embodiments, numbers expressing quantities of ingredients, properties such as molecular weight, reaction conditions, and so forth, used to describe and claim certain embodiments of the present disclosure are to be understood as being modified in some instances by the term “about.” In some embodiments, the term “about” is used to indicate that a value includes the standard deviation of the mean for the device or method being employed to determine the value. In some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable. The numerical values presented in some embodiments of the present disclosure may contain certain errors necessarily resulting from the standard deviation found in their respective testing measurements. The recitation of ranges of values herein is merely intended to serve as a shorthand method of referring individually to each separate value falling within the range. Unless otherwise indicated herein, each individual value is incorporated into the specification as if it were individually recited herein. The recitation of discrete values is understood to include ranges between each value.

In some embodiments, the terms “a” and “an” and “the” and similar references used in the context of describing a particular embodiment (especially in the context of certain of the following claims) can be construed to cover both the singular and the plural, unless specifically noted otherwise. In some embodiments, the term “or” as used herein, including the claims, is used to mean “and/or” unless explicitly indicated to refer to alternatives only or the alternatives are mutually exclusive.

The terms “comprise,” “have” and “include” are open-ended linking verbs. Any forms or tenses of one or more of these verbs, such as “comprises,” “comprising,” “has,” “having,” “includes” and “including,” are also open-ended. For example, any method that “comprises,” “has” or “includes” one or more steps is not limited to possessing only those one or more steps and can also cover other unlisted steps. Similarly, any composition or device that “comprises,” “has” or “includes” one or more features is not limited to possessing only those one or more features and can cover other unlisted features.

All methods described herein can be performed in any suitable order unless otherwise indicated herein or otherwise clearly contradicted by context. The use of any and all examples, or exemplary language (e.g., “such as”) provided with respect to certain embodiments herein is intended merely to better illuminate the present disclosure and does not pose a limitation on the scope of the present disclosure otherwise claimed. No language in the specification should be construed as indicating any non-claimed element essential to the practice of the present disclosure.

Groupings of alternative elements or embodiments of the present disclosure disclosed herein are not to be construed as limitations. Each group member can be referred to and claimed individually or in any combination with other members of the group or other elements found herein. One or more members of a group can be included in, or deleted from, a group for reasons of convenience or patentability. When any such inclusion or deletion occurs, the specification is herein deemed to contain the group as modified thus fulfilling the written description of all Markush groups used in the appended claims.

All publications, patents, patent applications, and other references cited in this application are incorporated herein by reference in their entirety for all purposes to the same extent as if each individual publication, patent, patent application, or other reference was specifically and individually indicated to be incorporated by reference in its entirety for all purposes. Citation of a reference herein shall not be construed as an admission that such is prior art to the present disclosure.

Having described the present disclosure in detail, it will be apparent that modifications, variations, and equivalent embodiments are possible without departing from the scope of the present disclosure defined in the appended claims. Furthermore, it should be appreciated that all examples in the present disclosure are provided as non-limiting examples.

### EXAMPLES

The following non-limiting examples are provided to further illustrate the present disclosure. It should be appreciated by those of skill in the art that the techniques disclosed in the examples that follow represent approaches the inventors have found function well in the practice of the present disclosure, and thus can be considered to constitute examples of modes for its practice. However, those of skill in the art should, in light of the present disclosure, appreciate that many changes can be made in the specific embodiments that are disclosed and still obtain a like or similar result without departing from the spirit and scope of the present disclosure.

### Example 1—Fabrication and Characterization of 8-Lead Structure on Diamond Culet

Presented herein is a fabrication procedure to produce high-quality liftoff structures on diamond anvils that extend continuously from the culet onto the slanted facets. Feature sizes as small as 500 nm are achieved using a trilayer resist stack and electron beam lithography. Device structures with strong adhesion to the diamond surface and high abrasion resistance are realized by optimizing the surface treatment. To benchmark this process, a multi-lead tungsten circuit was fabricated to measure changes in the superconducting transition temperature of zirconium across the structural phase transition at 30 GPa, revealing a nearly fourfold increase in the critical temperature. This method enables reproducible, high-resolution circuit fabrication on diamond anvils and other faceted crystalline substrates.

### BACKGROUND

Pressure is a fundamental thermodynamic variable that governs a material's equation of state. By controlling the pressure on the sample, one can selectively tune the properties of the material both reversibly and irreversibly. Historically, control over high pressure has lagged behind that of other thermodynamic parameters such as temperature or magnetic field. To achieve access to extreme pressures, diamond anvil cells (DACs) have been utilized in the last century, enabling static pressures exceeding 1 TPa.

The DAC was designed and implemented for infrared spectroscopy experiments on calcite and aragonite. This was achieved by clamping powders of interest directly between two diamonds with no gasket or pressure medium. The metal gasket with a hole was introduced to increase hydrostaticity and the technique was further improved to reach pressures up to 40 GPa. Beveled anvils were used to reach static pressures well above 100 GPa. To date, the highest static pressures generated are tera-pascal pressures, which was achieved in 2016.

Until the 1970s, all the experimental techniques carried out inside a DAC were done with optical measurements. A two-wire measurement scheme was devised with a gasketed cell and liquid pressure medium. Much work has been done to introduce leads into the diamond anvil cell sample space to perform electrical measurements at high pressures. Sputtered contacts for precision electrodes were introduced in 1984 and this paved the way for the modern-day techniques developed for patterned diamond anvils. A process was developed for encapsulating the electrode circuits under epitaxially grown diamonds to prevent shearing at high pressures. Boron-doped diamond was also used in some works as shear-resistant electrical contact leads. These improved fabrication approaches have advanced electronic characterization at high pressures and prompted a breadth of pioneering studies that deepen the understanding of compressed states of matter.

Demonstrated herein is a high-yield fabrication process for complex mesoscopic circuits on faceted crystalline structures. This process can be easily reproduced in a typical academic or industrial cleanroom environment. Specifically, a procedure was developed to obtain good focus at the diamond culet for electron beam lithography, which allows us to reach feature sizes down to 500 nm with liftoff layers. Strong adhesion is achieved by optimizing the treatment of the diamond surface before metal deposition.

To benchmark the device performance, the structural phase transition of zirconium metal inside the DAC was explored. Patterned leads were used for a four-wire measurement to observe the discontinuous jump in the superconducting transition temperature upon increasing pressure. This observation demonstrates the robust performance of the patterned leads in a high-pressure environment.

### Fabrication Process

FIG. 1 provides a step-by-step depiction of the fabrication process disclosed herein to lay down electrical leads. The process starts with a five-step cleaning process that begins with ultrasonic cleaning in Kayaku Remover PG to remove silver epoxy from previous experiments, then acetone to remove any oils, followed by sequential baths in aqua regia, piranha solution, and finally Transene Nb etchant (HF+HNO₃). All cleaning steps are performed for 10 min in duration. Most of the acid treatments are performed to remove devices fabricated previously on the diamond. For a newly purchased diamond, the acid cleaning procedures may be skipped partially or entirely.

The cleaned diamond is secured onto a 1 cm² carrier chip hand cleaved from a typical Si wafer with silver epoxy (EPO-TEK H20E). The diamond is mounted so that the table is in direct contact with the chip surface, ensuring the culet is relatively flat for lithography. A spin coat of a trilayer resist stack of the Kayaku PMMA copolymer EL 13/Kayaku PMMA copolymer EL 13/ZEP 520 A- 7 electron beam resist onto the diamond surface. When spun at 3000 RPM and soft baked at 180° C. for 2 min, EL 13 has a thickness of 730 nm, and ZEP has a thickness of 270 nm. To determine the resist thickness, the resists is spun separately on a flat Si wafer using the same spin and bake recipe at the same temperature and humidity. The thickness is determined using ellipsometry. It is assumed that the resist thickness on the diamond sample is similar to what has been measured on the Si wafer. Empirically, it was found that liftoff metal layers leave a continuous ring around the culet edge, which shorts all structures when using only a single layer of EL 13 under the top resist. This is due to the resist layer cracking at the sharp culet edge and leaving an exposed trench around the perimeter of the culet. To prevent shorting at the culet edge, a spin coat of two layers of EL 13 and a single layer of ZEP is added onto the diamond surface, yielding a bottom layer thickness of 1460 nm to safely cover the culet-facet sharp edge, and a top layer thickness of 270 nm.

In multiple fabrication runs, it is repeatedly observed using an optical microscope that there is no obvious color gradient on the diamond culet after spin coating the resist. This suggests that the resist has a thickness variation of <20 nm, which is smooth enough for patterning features down to a few hundred nanometers. To guarantee continuous wiring across the culet edge where there may be thickness variation, the electron dose is increased at the edge region by 50% to ensure complete exposure. For enhanced mechanical durability, no features less than 3 μm are patterned over the culet edge.

Then, 20 nm of aluminum (Al) is deposited on top of the resist inside a Kurt J. Lesker PVD 75 DC magnetron sputter chamber to prevent the pattern from distorting due to charging effects during electron beam lithography. The diamond is loaded into an Elionix ELS-S50EX lithography system. After focusing the electron beam following the standard procedure of the tool, the diamond girdle vertices are identified. These features are 1 mm away from the culet, they can be identified without irradiating the culet itself. The coordinate of each vertex is recorded to construct a regular hexadecagon, which pinpoints the location of the center of the culet within 20 μm accuracy. The beam is jogged with the shutter closed to one of the culet corners and it is focused by adjusting only the z-height of the sample stage. The view area is set to 1 μm², allowing only a negligible fraction of the corner to be exposed during this procedure.

If a pattern needs to be true to center on the culet, two to four opposing culet corners serve as registration marks to achieve an alignment accuracy better than 100 nm. GenISys BEAMER is used to correct for proximity effects when patterning fine features. To pattern critical features on the side facets, the exact height and radial distance from the edge of the culet to the bottom edge of the pavilion is measured. The slope is calculated and the focal height is used as a function of distance radially along the facets. Written in is a 100 μm step in the z direction to maintain reasonable local focus on the slanted facet. This is done by inserting meta-commands into the writing software to do a manual z-height adjustment for separate write fields that is iterated along the radius of the diamond. Furthermore, typically high-resolution structures on the facets and over-dose down the changing z-height of the facets is avoided to accommodate for the out-of-focus beam as the flat substrate height changes. This results in degraded resolution and pattern fidelity at the nano/micrometer scale on the pattern down the facets, not affecting the large contact pads.

After the lithography step, the resist is developed at room temperature in ZED-N 50 for 1 min and in a 1:3 mixture of MIBK:IPA for 2 min, followed by a 15-s rinse in IPA. Subsequent process optimization revealed that ice-bath development enables single-exposure undercut profiles by exploiting the difference in clear dose in ZEP 520A-7 and EL 13 and their selective solubility in cold ZED-N50 and room-temperature MIBK:IPA.

Before depositing metal, the diamond surface is prepared with an O₂ plasma ashing treatment (100 W power, 15 sccm of O₂ flow, 20 s duration) to promote adhesion. O₂ plasma changes the surface energy of diamond to a more hydrophilic surface, which is favored by the metal for strong adhesion. Without O₂ plasma treatment, deposited metal layers exhibit poor adhesion and are easily removed with scotch tape exfoliation. The O₂ plasma ashing dramatically increases the adhesion, forming metallic circuits that are robust against scratching and exfoliation, and withstand high-pressure environments. Strong adhesion was achieved for Cr, Ti, Ta, Nb, W, Au, Al, Al₂O₃, and SiO₂ films using either electron beam evaporation or magnetron sputtering. These materials are deposited easily, readily available in most cleanrooms, and sufficiently robust to withstand pressurization over the culet edge, except Al and Au, which are used as oxide protection or conducting caps. It has been found that W, Ta, Cr, Ti, SiO₂, and Al₂O₃ stick well to diamond, acting as an adhesion layer for other materials if desired.

For the prototype device, 300 nm of W was deposited using a Kurt J. Lesker PVD 75 DC magnetron sputter system with a base pressure of 10⁻⁷ Torr. After deposition, the diamond is soaked in Remover PG at 65° C. for 12 h to promote liftoff of the unwanted metal. The silver epoxy used to attach the diamond onto the carrier wafer softens inside Remover PG, and the diamond can then be easily detached from the carrier wafer. The diamond should be free of any silver residue after liftoff, but can be further cleaned by careful abrasion cleaning followed by sonication in acetone if needed. Using the procedures described above, features down to 500 nm can be achieved repeatably (FIG. 2A, FIG. 2B, FIG. 5B).

### Fabrication of a 10-Lead Device

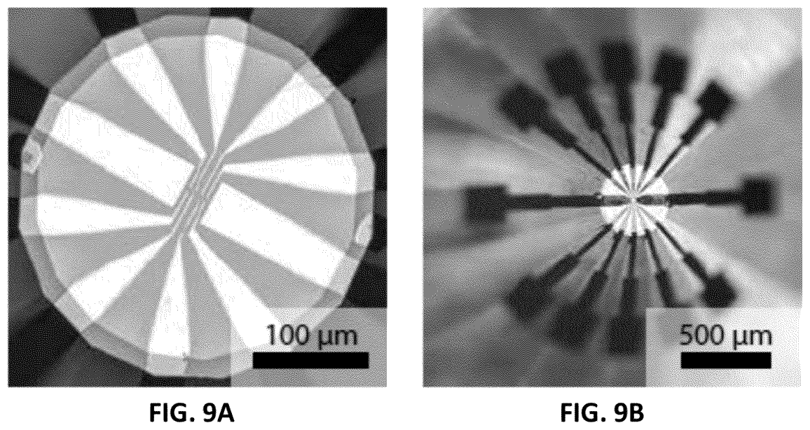

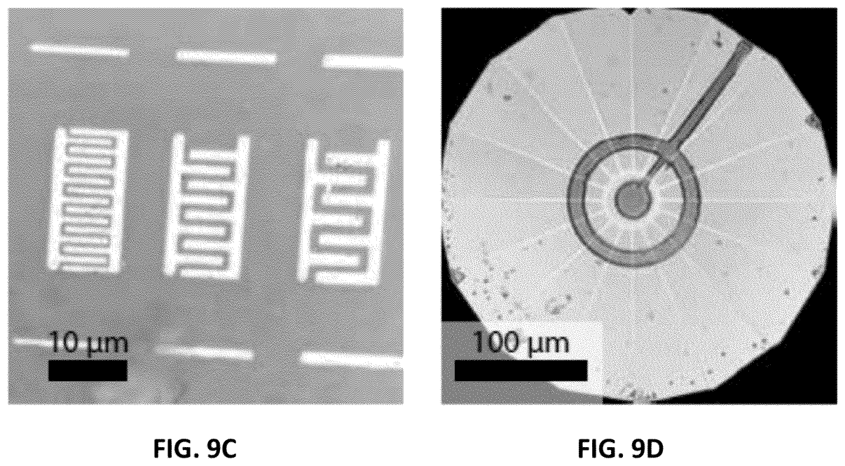

To validate the capability of this fabrication procedure, a 10-lead device is fabricated for electrical transport measurements using the methods with contact leads of 300 nm W on a single bevel type IIa diamond with a 400/450 μm culet/sub-culet (FIG. 9A). There are two metallic islands on opposing corners of the left and right sides of the culet. These are exposed areas used as focusing points and alignment marks during fabrication process step as disclosed herein. These may be removed with a UV laser drill if needed. Tungsten is chosen for the lead material due to its exceptionally high shear modulus of about 160 GPa, which provides strong resistance to deformation under pressure. In this testing, patterned leads remained mechanically and electrically intact across three separate loading cycles, each reaching up to 30 GPa, without observable delamination or fracture. While the adhesion energy or critical shear stress for the tungsten/diamond interface has not quantified, the repeated use of the same patterned diamond across multiple high-pressure experiments without lead failure provides compelling empirical evidence for the robustness of the fabrication approach for typical experimental conditions. The W test circuit for measuring Zr remains functional up to 51.1 GPa, the maximum pressure supported by the DAC.

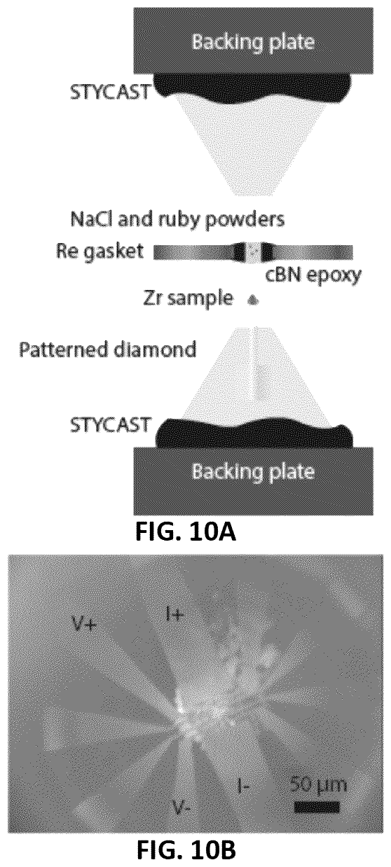

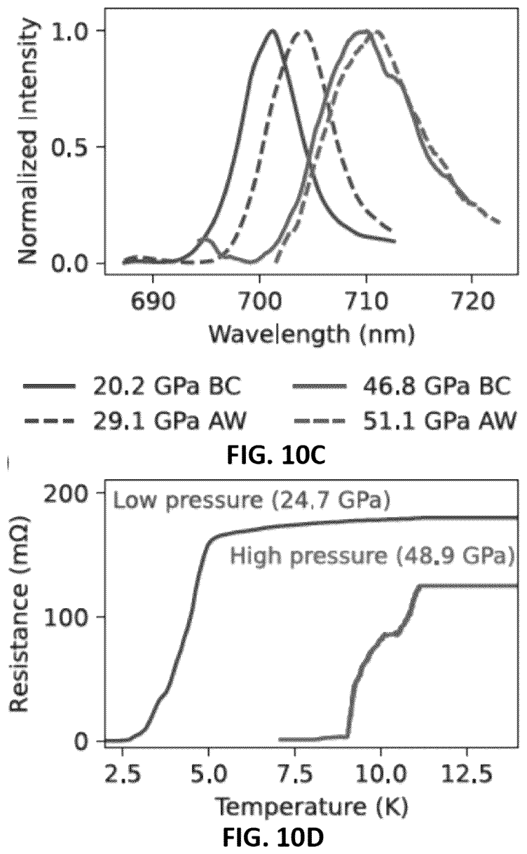

A thin sample of Zr with dimensions around 100×50×5 μm³ is prepared by polishing a Zr pellet, and placed onto the diamond culet over the patterned circuit using a sharpened toothpick (FIG. 10A). A set of patterned and anvil diamonds are mounted to 1 cm Inconel backing plates with a 1 mm, 30° chamfered through hole using LOCTITE STYCAST 2850FT with LOCTITE CAT 9 adhesive, cured at 65° C. for 2 h. To align the diamonds, the standard procedure to align the culet edges and corners is used since the edges and corners are still visible with the pattern on the diamond. The mounted diamonds are placed into the cell and coarsely aligned visually by looking at the overlap of the culets when brought close together. Once the coarse alignment is done, fine alignment is done by looking through both diamonds under a 20 × microscope and aligning the edges and corners of the culets on both diamonds while maintaining a small gap between the culets so the movement does not shear the leads. The gap is not measured, but is sufficiently smaller than the diameter of the culet for precise alignment. The Re gasket is pre-indented to 40 μm using a separate diamond of the same dimensions as the patterned diamond. Alternatively, the diamond to be patterned can be used for gasket preparation before patterning. Cubic boron nitride (cBN) nanopowder is mixed with a small amount of STYCAST 1266 A/B and cured at 65 C for 2 h. The resulting cBN-epoxy mixture is pressed into and around the drilled hole in the gasket to provide electrical insulation to the leads. Additionally, the cBN-epoxy insulating layer on the gasket surface introduces a mechanically compliant interface between the tungsten leads and the surrounding diamond and gasket materials. This layer mitigates shear stress concentration and adds mechanical buffering during pressurization, further reducing the likelihood of lead damage. To form the sample chamber, an about 300 μm hole is cut at the center of the gasket through the epoxy using an approximately 250 μm tungsten carbide end mill. NaCl pressure transmitting medium is loaded into the sample chamber along with fine ruby nanopowder to serve as a manometer. Finally, the cell is closed and mounted in a screw-driven plate-type DAC to apply pressure to the aligned diamonds. FIG. 10B shows an optical image of the closed cell at 15 GPa. 32 gauge Cu wires are silver epoxied to the contact pads on the diamond facets and soldered to external electronics. The pads are patterned at 500 μm width to facilitate wire attachment.

The pressure is measured across the culet at room temperature in the initially clamped cell using a 532 nm excitation laser and a SpectraPro HRS-750 spectrometer. The observed ruby fluorescence profile is fit to a Lorentzian distribution to determine the peak location and thereby determines the pressure. The initial pressure is determined to be 20.2 GPa (FIG. 10C, dark solid line). The cell is mounted into a Bluefors LD250 dilution refrigerator, and a Lake Shore Model 372 AC resistance bridge is used to measure the resistance with 100 μA excitation current in the 632 mΩ setting. The resistance vs temperature at the first clamped pressure (FIG. 10D) has a T_{c} of 4.3 K. After the measurement, the pressure is determined again at room temperature and is found to have increased to about 29.1 GPa (FIG. 10C, dark dashed line). Upon thermal cycling, the NaCl undergoes quasi-annealing at high pressure, causing grain boundaries to move and solidify. The shifting grains create inhomogeneous pressure across the sample face. FIG. 10C and FIG. 10D highlight the well-established quasi-hydrostatic nature of the solid NaCl pressure medium. Since pressure cannot be measured at cryogenic temperatures, the pressure of the sample is measured pre-and post-cooldown and the average is taken. The pressure is increased incrementally until a pressure of 46.8 GPa is achieved and was measured by the spectrometer before cooldown (FIG. 10C, light solid line). It was observed that the superconducting transition is broadened, with two transitions centered at 9.2 and 10.8 K (FIG. 10D). This is due to pressure inhomogeneity across the sample, which is also reflected in the fluorescence spectrum (FIG. 10C, light solid line), which shows a clear right-facing shoulder indicating multiple pressures across the measured area on top of the sample. FIG. 10C (light dashed line) shows the pressure to be 51.1 GPa at room temperature after the measurement with a more homogeneous pressure distribution after thermal cycling.

The substantial enhancement of critical temperature has been previously reported due to a first-order HCP to BCC structure transition. Previously, it was reported that the critical temperature was 9.2 K at 48 GPa, which is in great agreement with this studies reported value of 9.2 K at 49 GPa. The 10.8 K value corresponds to the maximum in T_{c} reported for Zr at the phase transition near 30 GPa, indicating a pressure gradient over the sample space. To mitigate pressure inhomogeneity in sensitive experiments, the sample can be thinned down, and a more hydrostatic pressure medium can be used. The agreement between these results and published data demonstrates the effectiveness and reliability of this method for patterning diamond anvils. This consistency highlights the precision and robustness of this approach, which achieves micrometer-scale resolution.

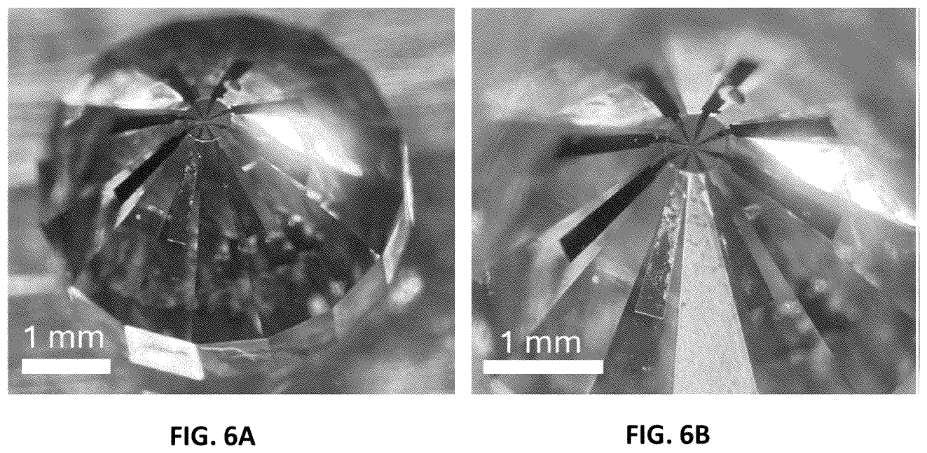

Shown herein are sub-micron liftoff structures fabricated on diamond culets. Using a benchmark device designed for electrical resistivity measurements, the increase in T_{c} is measured across a structural phase transition at 30 GPa, which demonstrates the device's compatibility with high-pressure and cryogenic environments. To date, the devices have been tested at pressures up to 50 GPa, and temperatures from 20 mK to room temperature. These devices and methods can fabricate various circuits (FIG. 6A, FIG. 9C, FIG. 9D). The improved device yield and quality, combined with a much smaller critical feature size, lay the foundation for fabricating high-quality mesoscopic circuits with more complex designs on diamond culets and faceted crystal samples. This method further enables a range of experiments, including magnetometry using nitrogen vacancy centers in diamond, gated heterostructure and Hall bar devices, AC calorimetry using precision deposited thermocouples, superconducting microwave resonators, and AC magnetic susceptibility with counter-wound coils. This process can be easily reproduced in a typical academic cleanroom and has applications in other methods using diamond anvil cells.

### Example 2—Fabrication and Characterization of 8-Lead Structure on Diamond Culet

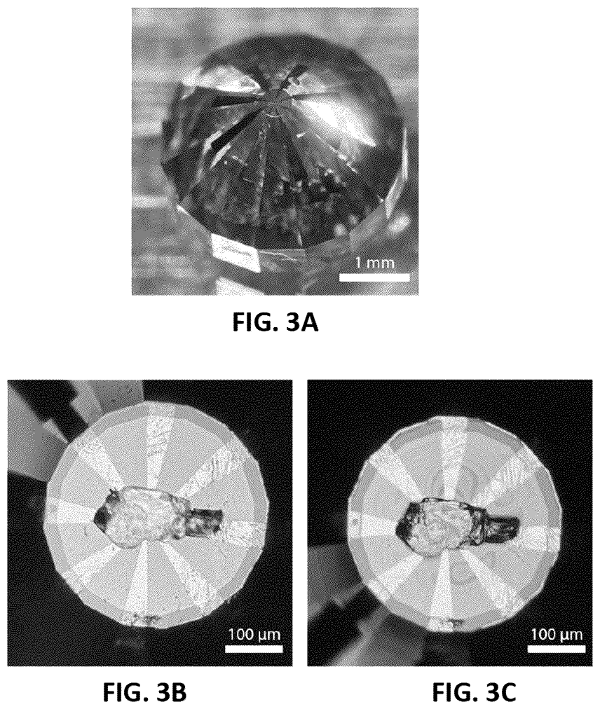

To demonstrate the performance of a mesoscopic circuit formed on the surface of a diamond in the context of a diamond anvil cell (DAC) experiment, the following experiments were conducted. The disclosed method was used to fabricate a simple mesoscopic circuit that included an 8-lead structure typically used for electrical resistance measurements in diamond anvil cell (DAC) experiments. A photo of the patterned diamond with leads is shown in FIG. 3A. A micron-sized sample was placed on the surface of the patterned diamond (FIG. 3B), and the sample was secured using SU-8 photoresist spin coated over the sample and patterned diamond, as illustrated in FIG. 3C.

The patterned diamond was installed in a diamond anvil cell (DAC) similar to the DAC illustrated schematically in FIG. 11. The Re gasket of the DAC was further insulated by depositing about 300 nm of SiOₓ using RF magnetron sputtering.

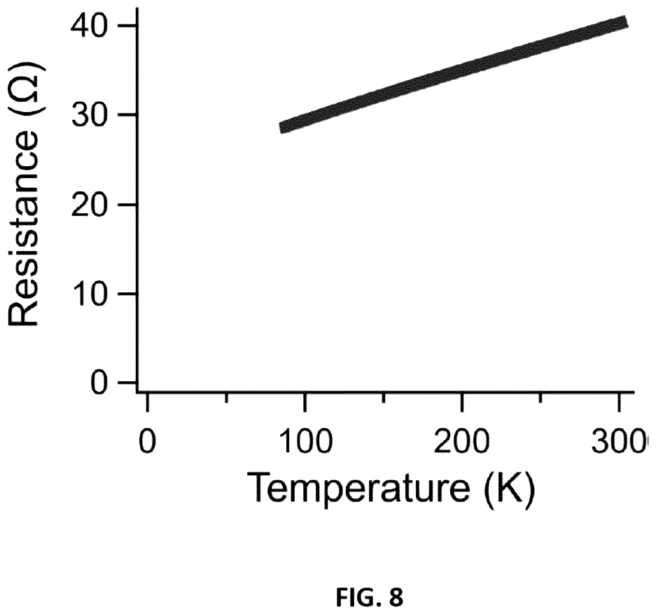

At a modest pressure of 1 GPa, the contact resistance of all leads on the patterned diamond dropped to about 100Ω. The metal leads encapsulated with SU-8 inside the DAC loaded with the SiOₓ-coated gasket exhibited metallic temperature dependence in electrical resistance (FIG. 8) and survived at pressures up to about 50 GPa until being shorted to the gasket or torn apart.

The results of these experiments demonstrated the feasibility of fabricating high quality mesoscopic circuits on diamond culets using the fabrication method disclosed herein and validated the disclosed method as a viable method for fabricating more complex device structures for probing materials properties using the DAC experimental set-up.

To validate the disclosed fabrication procedure and to characterize a patterned diamond surface, the following experiments were conducted. A diamond anvil patterned with 8 radially distributed leads was fabricated using the fabrication process disclosed herein. This patterned diamond anvil is representative of those used for electrical transport measurements within diamond anvil cell experiments. For convenient connection to measurement apparatus, the leads were extended about 1 mm onto the facets of the diamond as shown in FIG. 3A. The patterned diamond was attached onto a WC backing plate using STYCAST 2850FT epoxy and Pt wires were attached onto the contact pads deposited onto the diamond facets using DuPont silver paint. The Pt wires were soldered to Cu wires to electrically couple the patterned diamond to measurement equipment. The bottom half of the diamond anvil cell was assembled, and the patterned diamond was gently cleaned with an isopropyl alcohol-soaked cotton swab.

A sample consisting of an exfoliated piece of UTe₃ crystal was loaded over the eight leads on the patterned diamond. The sample was placed at the center of the culet of the patterned diamond as shown in FIG. 3B. SU-8 photoresist was spin coated at 3000 RPM over the culet and at 60° C. and 95° C. for 1 minute each sample and baked to form a ~2.4 μm thick protective layer on top of the sample. As shown in FIG. 3C, the sample stayed at the same position after the spin coating procedure. A Re gasket was coated with ~300 nm of SiOₓ using RF magnetron sputtering to further prevent the gasket metal from shorting the electrical leads. The sample was loaded into the DAC using the coated gasket and Daphne oil as the pressure medium. Ruby dust was added to the Daphne oil to measure the hydrostatic pressure inside the DAC. At a modest pressure of ~1 GPa, the contact resistance between the crystal and the leads dropped to about 100Ω, which was low enough for four-point resistance measurements.

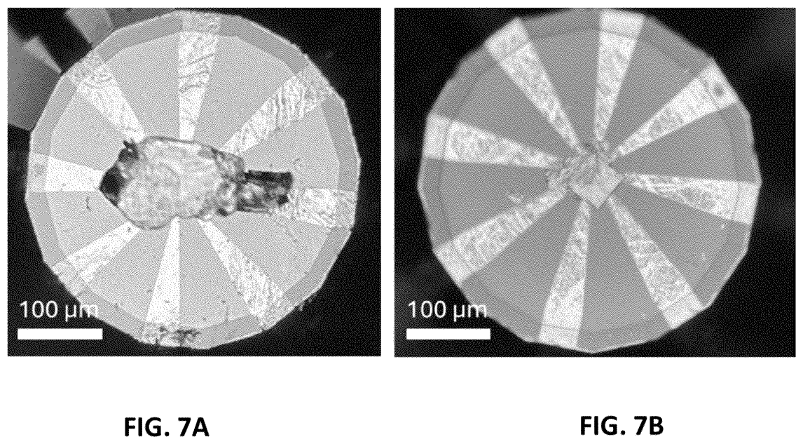

To further characterize the quality of the metals deposited onto diamond surfaces using the fabrication method disclosed herein, a second device was fabricated on a diamond. The device contained two continuous metal wires that were 200 μm long and 5 μm wide. The temperature dependence of the electrical resistance of these wires was measured at temperatures ranging from about 300 K to about 77 K inside a Quantum Design Physical Property Measurement System, and from about 100 K to about 10 mK inside a Bluefors LD250 dilution refrigerator. As shown in FIG. 7, the leads exhibited a metallic characteristic with a RRR of X. Y, and at ~0.45 K become superconducting due to the Ti film.

The second device was then loaded into the DAC using a SiOₓ-coated Re gasket and Daphne oil to study its behavior at elevated pressures. The resistance of the device at room temperature was measured as a function of pressure inside the DAC. No sudden change in device resistance was observed as the pressure steadily increased to above 40 GPa. This result suggested that the SiOₓ-coated Re gasket did not short the leads and the leads remained intact under high pressures within the DAC.

The temperature of the DAC containing the second device was swept at a pressure of 10 GPa to evaluate temperature-dependent changes in resistance. The temperature dependence was still metallic while the RRR dropped to 2.3 and the superconducting critical temperature increased to 0.7 K under the increased pressure. This result suggested that both the device and insulation technique within the DAC can survive cryogenic temperatures.

### Example 3—Sub-Micron Circuit Fabrication on Diamond Anvils for Mesoscopic High-Pressure Experiments

To validate a fabrication procedure to produce high-quality lift-off structures on diamond anvils extending from the culet down to the slanted facets, the following experiments were conducted. Feature sizes down to 500 nm are achieved through the use of a bi-layer resist stack and electron beam lithography. Device structures with strong adhesion to the diamond surface and high abrasion resistance are realized by optimizing the surface treatment. To benchmark the process, a multi-lead tungsten circuit is fabricated to measure changes of the superconducting transition temperature of zirconium across the structural phase transition at ~30 GPa; showing a 4-fold jump of the critical temperature. The process is easily reproducible in most traditional academic and industrial cleanroom facilities. This work paves the way for complex and high-precision fabrication and measurements inside diamond anvil cells and on other faceted crystalline samples.

The results of these experiments demonstrated a high-yield fabrication process for complex mesoscopic circuits on faceted crystalline structures. The process can be easily reproduced in typical academic or industrial cleanroom environments. Specifically, a procedure to obtain good focus at the diamond culet for electron beam lithography is developed, which allows one to reach feature sizes down to 500 nm with lift-off layers. Strong adhesion is achieved by optimizing the treatment of the diamond surface before metal deposition.

To benchmark the device performance, the structural phase transition of zirconium metal inside the DAC is measured. Patterned leads for a four-wire measurement are used to observe the discontinuous jump in the superconducting transition temperature upon increasing pressure. This observation demonstrates the robust performance of the patterned leads in a high-pressure environment.

FIG. 1 provides a step-by-step depiction of the fabrication process to lay down electrical leads. The process starts with a five step cleaning process. This starts with ultrasonic cleaning in Kayaku Remover PG to remove silver epoxy from previous experiments, then acetone to remove any oils, followed by sequential baths in aqua regia, Transene Nb etchant (HF+HNO3), and piranha solution. All cleaning steps are performed for 10 minutes in duration. The as-cleaned diamond is secured onto a 1 cm² carrier chip hand cleaved from a typical Si wafer with silver epoxy (EPO-TEK H20E). It is ensured that the diamond table is in direct contact with the chip surface, which ensures that the culet is relatively flat for the lithography step. A bi-layer resist stack of Kayaku PMMA copolymer EL 13/ZEP 520A-7 electron beam resist is spin coated onto the diamond surface. When spun at 3000 RPM and soft baked at 180° C. for 2 minutes, EL 13 has a thickness of 730 nm, and ZEP has a thickness of 270 nm. 2 layers of EL 13 and a single layer of ZEP are spun in the procedure, yielding a bottom layer thickness of 1460 nm to safely cover the culet-facet sharp edge, and a top layer thickness of 270 nm. The top layer has a higher clear dose than the bottom layer. This allows the bottom layer to form an undercut, which significantly improves the quality of lift-off structures.

~20 nm of Al is then deposited on top of the resist inside a Kurt J. Lesker PVD 75 DC magnetron sputter chamber to prevent the pattern from distortion due to charging effects during electron beam lithography. The diamond is then loaded into an Elionix ELS-S50EX lithography system. After focusing the electron beam following the standard procedure of the tool, the diamond girdle vertices are searched for. As these features are ~1 mm away from the culet, they can be found easily without exposing the culet to the electron beam. The coordinate of each vertex is recorded to construct a regular hexadecagon which allows one to locate the center of the culet within 20 μm accuracy. The beam is jogged to one of the corners of the culet and the beam is focused on that corner by adjusting the Z-height of the sample stage. The view area can be set with a size ~1 μm² allowing only a negligible fraction of the corner to be exposed during this procedure. Two to four opposing culet corners are used as registration marks to achieve an alignment accuracy better than 100 nm. GenISys BEAMER is used to correct for proximity effects when patterning fine features. After the lithography step, the resist is developed at room temperature in ZED-N 50 for 1 minute and in a 1:3 mixture of MIBK:IPA for 2 minutes, followed by a 15-second rinse in IPA.

Before depositing metal, the diamond surface is prepared with a O₂ plasma ashing treatment (100 W power, 15 sccm of O2 flow, 20 s duration) to promote adhesion. Strong adhesion is achieved for Cr, Ti, Ta, Nb, W, Au, Al, and SiO₂ films using either electron beam evaporation or magnetron sputtering. For the prototype device, 300 nm of W is deposited using a Kurt J. Lesker PVD 75 DC magnetron sputter system with base pressure of ~10-7 Torr.

After deposition, the diamond is soaked in Remover PG at 65° C. for 12 hours to promote liftoff of the unwanted metal. The silver epoxy used to attach the diamond onto the carrier wafer softens inside Remover PG and the diamond can then be easily detached from the carrier wafer. The diamond should be free of any silver residue after lift-off but can be further cleaned by careful abrasion cleaning followed by sonication in acetone if needed. Using the procedures described above, features down to 500 nm can be achieved repeatably as shown in FIGS. 2A, 2B, and 5B.

To benchmark the capability of the fabrication procedure, a 10-lead device is fabricated for electrical transport measurements using the methods with contact leads of 300 nm W on a single bevel type IIa diamond with a 400/450 μm culet/sub-culet as shown in FIG. 9A. Tungsten leads are chosen due to their resistance to physical abrasion which allows one to repeatedly use the same patterned device to measure multiple samples.

As illustrated in FIG. 10A, a thin sample of Zr with dimensions ~100×50×5 μm³ is prepared by polishing a Zr pellet. The Zr sample is placed onto the diamond culet over the patterned circuit using a sharpened toothpick. A set of patterned and anvil diamonds are mounted to 1 cm Inconel backing plates with a 1 mm, 30 degree chamfered through hole using LOCTITE STYCAST 2850FT with LOCTITE CAT 9 adhesive, cured at 65° C. for 2 hours. The Re gasket is pre-indented to 40 μm and a 350 μm hole is drilled using a drill press. Cubic boron nitride (cBN) nanopowder is mixed with a small amount of STYCAST 1266 A/B and cured at 65° C. for 2 hours. The resulting cBN epoxy mixture is pressed into and around the drilled hole in the gasket to provide electrical insulation to the leads. To form the sample chamber, a ~300 μm hole is cut at the center of the gasket through the epoxy using a ~250 μm tungsten carbide end mill. NaCl pressure transmitting medium is loaded into the sample chamber along with fine ruby nano-powder to serve as a manometer. Finally, the cell is closed and mounted in a screw-driven plate type DAC to apply pressure to the aligned diamonds. FIG. 10B shows an optical image of the closed cell at ~15 GPa. 32 gauge Cu wires are silver epoxied to the contact pads on the diamond facets and soldered to external electronics. The pads are patterned to be 500 μm to provide ample space to attach larger gauge wires without the risk of shorting.

The pressure across the culet at room temperature in the initially clamped cell is measured using a 532 nm excitation laser and a SpectraPro HRS-750 spectrometer. The observed ruby fluorescence profile is fit to a Lorentzian distribution to determine the peak location, and thereby determine the pressure. The initial pressure is determined to be 20.2 GPa as shown in FIG. 10C (red solid line). The cell is mounted into a Bluefors LD250 dilution refrigerator, and a Lake Shore Model 372 AC resistance bridge is used to measure the resistance with 100 μA excitation current in the 632 mΩ setting. The resistance vs. temperature at the first clamped pressure is shown in FIG. 10D with a Tc of 4.3 K. After the measurement, the pressure is measured again at room temperature and is found to have increased to about 29.1 GPa as shown in FIG. 10C (red dashed line). Since it is not possible to measure the pressure at cryogenic temperatures, the pressure on the sample is taken to be the average of the pre- and post-cooldown pressures. The pressure is increased incrementally until a pressure of 46.8 GPa measured by the spectrometer is achieved (FIG. 10C (green solid line)). It is observed that the superconducting transition is broadened, with two transitions centered at 9.2 K and 10.8 K as seen in FIG. 10D. This is due to the pressure inhomogeneity across the sample, which is also reflected in the florescence spectrum FIG. 10C (green solid line), which shows a clear right facing shoulder indicating multiple pressures across the measured area on top of the sample. FIG. 10C (green dashed line) shows the pressure to be 51.1 GPa at room temperature after the measurement with a more homogeneous pressure distribution after thermal cycling.

The dramatic increase in the critical temperature has been previously reported due to a first order HCP to BCC structure transition. The agreement between the measured results and published data demonstrates the effectiveness and reliability of the method for patterning diamond anvils. This consistency highlights the precision and robustness of the approach, which successfully achieves micrometer-scale resolution.

In these experiments, sub-micron lift-off structures fabricated on diamond culets were successfully demonstrated. Using a benchmark device designed for electrical resistivity measurements, the increase of Tc across a structural phase transition at ~30 GPa was measured, which demonstrated the device's compatibility with high pressure and cryogenic environments. FIGS. 3, 5, 6, 7, and 9 presented various circuits fabricated during process development. The improved device yield and quality, combined with a much smaller critical feature size, provides a method for fabricating high quality mesoscopic circuits with more complex designs on diamond culets and faceted crystal samples. It is anticipated the fabrication procedure will enable novel experiments involving, for example, magnetometry using nitrogen vacancy centers in diamond, gated heterostructure and hall bar devices, AC calorimetry using precision deposited thermocouples, superconducting microwave resonators, and AC magnetic susceptibility with counter-wound coils. It is expected the disclosed process can be easily reproduced in a typical academic cleanroom, creating opportunities for future groundbreaking experiments using diamond anvil cells.

What is claimed is:

1. A process for fabricating a mesoscopic circuit on a diamond surface for use in diamond anvil cell (DAC) experiments, the process comprising:
a. providing a diamond and a flat substrate;
b. mounting the diamond pressed flat against the flat substrate to ensure a flat diamond surface for fabricating the mesoscopic circuit;
c. spin-coating the flat diamond surface with a bi-electron beam resist layer comprising a bottom resist layer in direct contact with the flat diamond surface and a top resist layer over an exposed surface of the bottom resist layer;
d. depositing a metal layer over the bi-electron beam resist layer;
e. removing a selected portion of the metal layer and underlying bi-electron beam resist layer to expose a portion of the diamond surface in a pattern corresponding to one or more elements of the mesoscopic circuit using an E-lithography system;
f. depositing at least one electrically conductive layer over the exposed portion of the diamond surface and a portion of the metal layer; and
g. lifting off an unwanted portion of the at least one conductive layer and underlying metal layer and bi-electron beam resist layer to expose the mesoscopic circuit on the diamond surface.

2. The process of claim 1, wherein the diamond is a type IIa single-beveled diamond with a 400 μm wide culet.

3. The process of claim 1, wherein the flat substrate comprises silicon (Si).

4. The process of claim 3, wherein the flat substrate comprises a 1 cm² carrier chip hand cleaved from a Si (100) wafer.

5. The process of claim 1, wherein top resist layer comprises a ZEP 520A-7 copolymer and the bottom resist layer comprises a EL 13 copolymer.

6. The process of claim 5, wherein the top resist layer comprises a thickness of about 270 nm and the bottom resist lay comprises a thickness of about 1460 nm.

7. The process of claim 1, wherein the top resist layer and the bottom resist layer are spin coated onto the diamond surface at a spin rate of about 3000 RPM of spin rate and soft baked at about 180° C for about 2 minutes.

8. The process of claim 1, wherein the metal layer comprises Al.

9. The process of claim 8, wherein the Al is deposited over the bi-electron beam resist layer using a magnetron sputter chamber or an electron bean evaporation chamber with a base pressure ranging from about 10⁻⁶ to about 10⁻⁷ Torr.

10. The process of claim 1, further comprising cleaning the diamond in at least one ultrasound bath, each ultrasound bath containing one solvent selected from toluene to remove silver epoxy, acetone to remove any oils, aqua regia to dissolve attached metals, Cr etchant to dissolve attached Cr, Nb etchant to dissolve attached Nb, or piranha solution to dissolve attached organic residue.

11. The process of claim 10, wherein the diamond is cleaned for a duration of about 10 minutes in each ultrasound bath.

12. The process of claim 1, wherein mounting the diamond to the flat substrate comprises attaching the diamond to the Si flat substrate using a silver epoxy adhesive.

13. The process of claim 1, wherein each of the at least one conductive layers comprise a metal independently selected from Al, Au, Cr, Ta, Ti, Nb, W, any alloy thereof, and any combination thereof.

14. The process of claim 1, further comprising preparing the exposed diamond surface for deposition of the at least one conductive layer using an O₂ plasma ashing treatment.

15. The process of claim 1, further comprising soaking the diamond mounted to the flat substrate in Kayaku Remover PG at a temperature of about 65° C for a duration of about 12 hours.

16. The process of claim 15, further comprising removing the diamond and fabricated mesoscopic circuit from the flat substrate.

17. The process of claim 1, wherein the mesoscopic circuit is selected from an 8-lead electrode pattern, a 10-lead electrode pattern, at least two parallel leads, a pair of intercalated fingers, and any combination thereof.

18. The process of claim 1, wherein the mesoscopic circuit comprises a minimum feature size of about 500 nm.

19. The process of claim 10, further comprising removing an amount of silver epoxy from the diamond by abrasion, sonication in toluene, and any combination thereof.

20. A patterned diamond comprising a mesoscopic circuit formed on a diamond surface using a fabrication process comprising:
a. providing a diamond and a flat substrate;
b. mounting the diamond pressed flat against the flat substrate to ensure a flat diamond surface for fabricating the mesoscopic circuit;
c. spin-coating the flat diamond surface with a bi-electron beam resist layer comprising a bottom resist layer in direct contact with the flat diamond surface and a top resist layer over the exposed surface of the bottom resist layer;
d. depositing a metal layer over the bi-electron beam resist layer;
e. removing a selected portion of the metal layer and underlying bi-electron beam resist layer to expose a portion of the diamond surface in a pattern corresponding to one or more elements of the mesoscopic circuit using an E-lithography system;
f. depositing at least one electrically conductive layer over the exposed portion of the diamond surface and a portion of the metal layer; and
g. lifting off an unwanted portion of the at least one conductive layer and underlying metal layer and bi-electron beam resist layer to expose the mesoscopic circuit on the diamond surface.
